(19) United States
(12) Patent Application Publication
(10) Pub. No.: US 2026/0053027 A1
(43) Pub. Date: Feb. 19, 2026

(54) PACKAGE WITH CARRIER HAVING COMPONENT ON PAD ON ONE SIDE AND OTHER PAD WITH TWO METALLIC AREAS ON OTHER SIDE

(71) Applicant: Infineon Technologies AG, Neubiberg (DE)

(72) Inventors: Guan Choon TEE, Melaka (MY); Hock Heng CHONG, Melaka (MY); Nurfarena OTHMAN, Melaka (MY); Chee Yang NG, Muar (MY)

(73) Assignee: Infineon Technologies AG, Neubiberg (DE)

(21) Appl. No.: 19/280,189

(22) Filed: Jul. 25, 2025

(30) Foreign Application Priority Data
Aug. 16, 2024 (DE) 10 2024 123 456.3

(51) Int. Cl. H01L 23/498; H01L 21/48; H01L 21/56; H01L 23/00; H01L 23/31

(52) U.S. Cl. CPC H01L 23/49838; H01L 21/4846; H01L 23/49894; H01L 24/16; H01L 21/56; H01L 23/3107; H01L 2224/16227

(57) ABSTRACT

A package is disclosed. In one example, the package comprises a carrier having a first main surface at which at least one first pad is formed and an opposing second main surface at which at least one second pad is formed at least partially in an electrically insulating layer structure of the carrier. An electronic component is mounted on or above the carrier, electrically connected with the at least one first pad and arranged spaced with respect to the at least one second pad by the carrier. The at least one second pad comprises a first metallic area facing the carrier and a second metallic area connected at an interface with the first metallic area and facing away from the carrier.

### CROSS-REFERENCE TO RELATED APPLICATION

This Utility patent application claims priority to German Patent Application No. 10 2024 123 456.3 filed Aug. 16, 2024, which is incorporated herein by reference.

### BACKGROUND

The present invention relates to a package, and to a method of manufacturing a package.

A package may comprise an electronic component, such as a semiconductor chip. Packages may be embodied as encapsulated electronic component with electrical connects extending out of the encapsulant and being coupled with an electronic periphery. A mold compound or a laminate may be used as encapsulant.

However, packages may suffer from mechanical stress during manufacture.

### SUMMARY

There may be a need to provide a package with reliable mechanical integrity.

According to an exemplary embodiment, a package is provided which comprises a carrier having a first main surface at which at least one first pad is formed and an opposing second main surface at which at least one second pad is formed at least partially in an electrically insulating layer structure of the carrier, and an electronic component mounted on or above the carrier, electrically connected with the at least one first pad and arranged spaced with respect to the at least one second pad by the carrier, wherein the at least one second pad comprises a first metallic area facing the carrier and a second metallic area connected at an interface with the first metallic area and facing away from the carrier.

According to another exemplary embodiment, a method of manufacturing a package is provided, the method comprising forming at least one first pad at a first main surface of a carrier, forming at least one second pad at an opposing second main surface of the carrier and at least partially in an electrically insulating layer structure of the carrier, mounting an electronic component on or above the carrier, electrically connected with the at least one first pad and arranged spaced with respect to the at least one second pad by the carrier, and forming the at least one second pad with a first metallic area facing the carrier and with a separately formed second metallic area connected at an interface with the first metallic area and facing away from the carrier.

According to an exemplary embodiment, a package (for instance a power package) is equipped with a carrier (such as a laminated substrate) with one or more first pads on a first main surface and with one or more second pads partially or entirely embedded in an electrically insulating layer structure (such as a patterned layer of solder resist) on the opposing other main surface. One or more electronic components (for instance a semiconductor power chip) are assembled electrically coupled with the at least one first pad on the carrier. Advantageously, the at least one second pad is composed at least of a carrier-sided first metallic area and an opposing second metallic area with an interface in between. In order to avoid undesired bending or warpage of the carrier when assembling the electronic component(s) thereon, the opposing second pad may comprise not only said first metallic area but in addition a reinforcing second metallic area which may efficiently suppress bending or warpage. Descriptively speaking, the at least one second pad comprising at least two stacked metallic areas may function as a reinforced pad. For instance, the second metallic area may be formed by step plating on the first metallic area for forming a big bottom pad providing effective mechanical support. Such a reinforced second pad may prevent or reduce pad bulging, associated chip crack, solder joint crack, and/or other undesired phenomena. As a result, a package with reliable mechanical integrity may be obtained.

### BRIEF DESCRIPTION OF THE DRAWINGS

The accompanying drawings, which are included to provide a further understanding of exemplary embodiments of the invention and constitute a part of the specification, illustrate exemplary embodiments of the invention.

In the drawings:

FIG. 1 shows a cross-sectional view of a package according to an exemplary embodiment.

FIG. 2 shows a transparent top view of a package according to an exemplary embodiment.

FIG. 3 shows a flowchart of a method of manufacturing a package according to an exemplary embodiment.

FIG. 4 shows a flowchart of a method of manufacturing a package according to an exemplary embodiment.

FIG. 5 shows cross-sectional views of structures obtained during manufacturing a package according to an exemplary embodiment.

FIG. 6 shows cross-sectional views of structures obtained during manufacturing a package according to another exemplary embodiment.

FIG. 7 shows a cross-sectional view of a package according to another exemplary embodiment together with a detail.

FIG. 8 shows a cross-sectional view of a molded interconnected substrate-type carrier for a package according to another exemplary embodiment.

FIG. 9 shows a cross-sectional image of part of a package according to an exemplary embodiment.

### DETAILED DESCRIPTION

There may be a need to provide a package with reliable mechanical integrity.

According to an exemplary embodiment, a package is provided which comprises a carrier having a first main surface at which at least one first pad is formed and an opposing second main surface at which at least one second pad is formed at least partially in an electrically insulating layer structure of the carrier, and an electronic component mounted on or above the carrier, electrically connected with the at least one first pad and arranged spaced with respect to the at least one second pad by the carrier, wherein the at least one second pad comprises a first metallic area facing the carrier and a second metallic area connected at an interface with the first metallic area and facing away from the carrier.

According to another exemplary embodiment, a method of manufacturing a package is provided, the method comprising forming at least one first pad at a first main surface of a carrier, forming at least one second pad at an opposing second main surface of the carrier and at least partially in an electrically insulating layer structure of the carrier, mounting an electronic component on or above the carrier, electrically connected with the at least one first pad and arranged spaced with respect to the at least one second pad by the carrier, and forming the at least one second pad with a first metallic area facing the carrier and with a separately formed second metallic area connected at an interface with the first metallic area and facing away from the carrier.

According to an exemplary embodiment, a package (for instance a power package) is equipped with a carrier (such as a laminated substrate) with one or more first pads on a first main surface and with one or more second pads partially or entirely embedded in an electrically insulating layer structure (such as a patterned layer of solder resist) on the opposing other main surface. One or more electronic components (for instance a semiconductor power chip) are assembled electrically coupled with the at least one first pad on the carrier. Advantageously, the at least one second pad is composed at least of a carrier-sided first metallic area and an opposing second metallic area with an interface in between. In order to avoid undesired bending or warpage of the carrier when assembling the electronic component(s) thereon, the opposing second pad may comprise not only said first metallic area but in addition a reinforcing second metallic area which may efficiently suppress bending or warpage. Descriptively speaking, the at least one second pad comprising at least two stacked metallic areas may function as a reinforced pad. For instance, the second metallic area may be formed by step plating on the first metallic area for forming a big bottom pad providing effective mechanical support. Such a reinforced second pad may prevent or reduce pad bulging, associated chip crack, solder joint crack, and/or other undesired phenomena. As a result, a package with reliable mechanical integrity may be obtained.

### DESCRIPTION OF FURTHER EXEMPLARY EMBODIMENTS

In the following, further exemplary embodiments of the package and the method will be explained.

In the context of the present application, the term “package” may particularly denote an electronic device which may comprise one or more electronic components mounted on a carrier. Said constituents of the package may be optionally encapsulated or covered at least partially by an encapsulant.

In the context of the present application, the term “carrier” may particularly denote a support structure (which may be at least partially electrically conductive) which serves as a mechanical support for the one or more electronic components to be mounted thereon, and which may also contribute to the electric interconnection between the electronic component(s) and the periphery of the package. In other words, the carrier may fulfil a mechanical support function and an electric connection function. A carrier may comprise or consist of a single part, multiple parts joined via encapsulation or other package components, or a subassembly of carriers.

In the context of the present application, the term “main surface” of a body may particularly denote the largest body surface of one of the largest body surfaces. For instance, a body (such as a carrier or an electronic component or part thereof) may be plate-shaped or substantially plate-shaped and may then have two opposing main surfaces separated by body material in a thickness direction and connected with each other by a circumferential edge.

In the context of the present application, the term “pad” may particularly denote (preferably flat and horizontal) electrically conductive terminals at a surface of a carrier. Such pads may function as an interface with a carrier periphery for transmission of electric signals and/or electric energy in an interior of the package and/or between an exterior and an interior of the package. A pad may also be electrically coupled with an electronic component for signal and/or energy transfer.

In the context of the present application, the term “insulating layer structure” may particularly denote an electrically insulating structure, which may be shaped as a layer, sheet or film. For example, an insulating layer structure may be patterned or may be composed of a plurality of separate islands.

In the context of the present application, the term “electronic component” may in particular encompass a semiconductor chip (in particular a power semiconductor chip), an active electronic device (such as a transistor), a passive electronic device (such as a capacitance or an inductance or an ohmic resistance), a sensor (such as a microphone, a light sensor or a gas sensor), a light emitting, semiconductor-based device (such as a light emitting diode (LED) or LASER), an actuator (for instance a loudspeaker), and a microelectromechanical system (MEMS). In particular, the electronic component may be a semiconductor chip having at least one integrated circuit element (such as a diode or a transistor) in a surface portion thereof. The electronic component may be a naked die or may be already packaged or encapsulated. Semiconductor chips implemented according to exemplary embodiments may be formed in silicon technology, gallium nitride technology, silicon carbide technology, etc.

In the context of the present application, the term “second metallic area connected at an interface with a first metallic area” may particularly denote a composition of the second pad which allows to distinguish the interface between the two metallic areas by inspection, for instance by visual inspection. When the first metallic area and the second metallic area are manufactured by different manufacturing processes, an optical inspection, a visual inspection, and/or a spectroscopic inspection, for instance an inspection of a cross-sectional analysis of the carrier with its second pad(s), may allow to identify the interface or boundary between the separate metallic areas. For instance, the first metallic area and the second metallic area may be made of different materials, so that the interface may be formed by a boundary between different materials. Alternatively, the first metallic area and the second metallic area may be made of the same material, however with a separating interface between. For instance, the first metallic area may be formed during a carrier manufacturing process, for instance a laminate substrate manufacture. For example, the second metallic area may be formed on the first metallic area during a packaging process during which the electronic component is assembled on the carrier and the second pad is thickened by adding the second metallic area on the first metallic area.

In an embodiment, a height difference between an exterior surface of the at least one second pad and an exterior surface of the electrically insulating layer structure is not more than 15 μm, for example not more than 10 μm, preferably not more than 5 μm. Correspondingly, the method may comprise forming the second metallic area on the first metallic area to thereby at least partially compensate a height difference between a bottom surface of the first metallic area and a bottom surface of the electrically insulating layer structure. Advantageously, said height difference may be rendered very small thanks to the addition of the second metallic area. This makes the package less prone to bending and cracking of the electronic component during processing, in particular during molding. By the second metallic area, the height difference may be at least partially compensated.

In an embodiment, an exterior surface of the at least one second pad does not protrude downwardly beyond an exterior surface of the electrically insulating layer structure. Either the exterior surface of the second pad may be in flush or vertical alignment with the exterior surface of the electrically insulating layer structure, or the electrically insulating layer structure may slightly protrude beyond the exterior surface of the second pad. Thus, the bottom main surface of the package may still be defined by the electrically insulating layer structure, for instance a solder resist. Hence, the footprint of the package will not be modified in comparison with conventional approaches. This may ensure that the package can be handled, from a user point of view, as conventional packages.

In an embodiment, the at least one second pad has a step. More specifically, a lateral step may be formed between the first metallic area and the second metallic area. Such a step may be a fingerprint of the manufacturing process in which the first metallic area is partially embedded in the patterned electrically insulating layer structure, whereas the second metallic area is formed on an exposed surface of the first metallic area or on part thereof.

In an embodiment, the carrier comprises a laminate substrate having an at least partially electrically insulating laminate between the first main surface and the second main surface. In the context of the present application, the term “laminate” may particularly denote a flat body (such as a sheet or plate) formed by multiple interconnected laminate layers, i.e. layers which can be or which are interconnected by lamination. In particular, a laminate may comprise a material that is suitable for sticking several laminate layers, for instance made of the same material, together. Hence, a laminate may be a plate-shaped or sheet-shaped body made of one or multiple laminable or laminated layers. Said laminate layers may be connected or configured to be connectable with other layers by lamination. Lamination may denote a connection of laminable layers using elevated temperature, optionally accompanied by an additional mechanical pressure applied to stacked laminate layers. In particular, such a laminate may be a pressed multilayer stack of one or more dielectric organic layers and/or one or more metallic foils. One or more dielectric laminate layers may be for example prepreg layers. Prepreg is a material which comprises a resin, optionally with glass particles therein. The laminate may also comprise one or more metal layers, which may be copper foils. More generally, the laminate may comprise at least one dielectric layer which is capable of curing, polymerizing and/or cross-linking during a lamination process, thereby contributing to an adhesion force between multiple layers of a multilayer laminate. For instance, a laminate may be a chip substrate or a printed circuit board (PCB).

In particular, a laminate material or material of the laminate may be an epoxy resin or another polymer (like polyimide) or another insulating material filled with filler particles, in particular glass particles, more particularly glass fibers. Such a material may be provided as prepreg, i.e. as a sheet in which the epoxy resin is not or not fully cured, so that it can become liquid by supplying thermal energy. In a laminate, such a prepreg sheet may be combined with one or more copper foils which can be attached upon lamination. Resin Coated Copper (RCC) is a combination of a copper foil and an uncured epoxy resin without glass fibers.

In another embodiment, the carrier comprises a molded interconnect substrate. A molded interconnect structure may comprise one or more molding layers in which one or more electrically conductive trace layers and/or one or more electrically conductive through connections may be embedded. As an alternative to a laminate substrate, it may be possible to use a mold substrate. For example, a Molded Interconnect Substrate (MIS) can be used. In particular, a routable carrier may have a solder mask or the like at the bottom where a gap to a mold cavity may be created. There may be bending stress during molding or another encapsulation process giving this bending stress on a big, exposed pad.

In yet another embodiment, the carrier may also be a leadframe, in particular with a solder mask. In the context of the present application, the term “leadframe” may particularly denote a sheet-like metallic structure which can be bent, punched and/or patterned so as to form leadframe bodies as mounting sections for mounting chips, and connection leads for electric connection of the package to an electronic environment. In an embodiment, the leadframe may be a metal plate (in particular made of copper) which may be patterned, for instance by stamping or etching. Forming a chip carrier as a leadframe is a cost-efficient and mechanically as well as electrically highly advantageous configuration in which a low ohmic connection of chips can be combined with a robust support capability of the leadframe. Furthermore, a leadframe may contribute to the thermal conductivity of the package and may remove heat generated during operation of the chip(s) as a result of the high thermal conductivity of the metallic (in particular copper) material of the leadframe.

In an embodiment, the at least one second pad is a double layer or a triple layer. For instance, it may be a double layer when being formed by the first and second metallic areas only. In addition, at least one third metallic area may be added and/or a surface finish may be added.

In an embodiment, the first metallic area extends over a wider spatial range than the second metallic area. Generally it may not be intended to overplate, mainly to close up a gap or make a gap smaller (so as to achieve a smaller bending stress). Preferably, a spatial difference between the sidewalls of the first metallic area and the second metallic area may be not more than ±5 μm. For instance, a vertical thickness of the second metallic area may be in a range from 5 μm to 30 μm, in particular in a range from 10 μm to 15 μm.

Alternatively, the second metallic area extends over a wider spatial range than the first metallic area. In practice, sometimes during plating the extension of the second metallic area is not controlled to be strictly limited and it may be bigger than the first metallic area, because the second metallic area may cover a small part of the solder mask. In such a scenario, the second metallic area has an area larger than the first metallic area and the bottom surface of the second metallic area may extend laterally beyond the bottom surface of the solder mask.

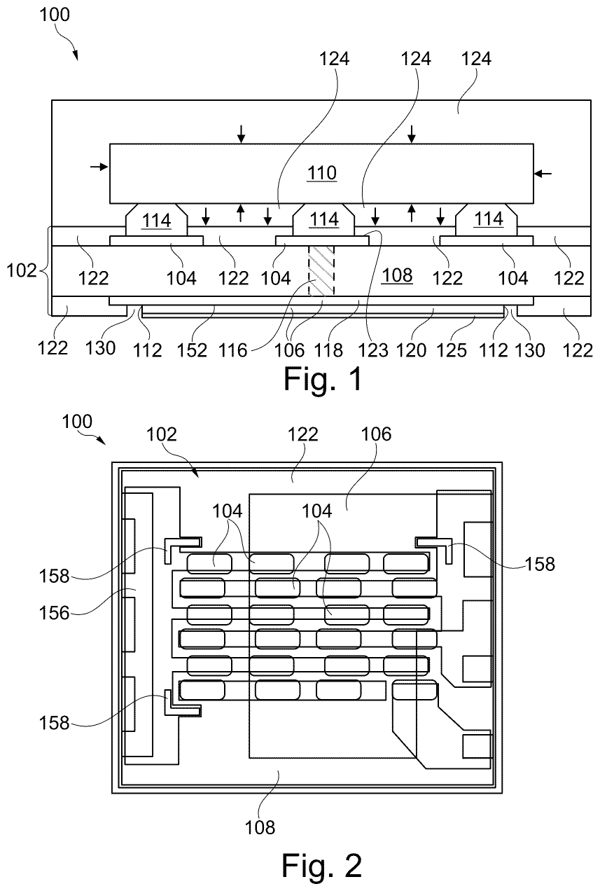

In an embodiment, the second metallic area lies completely inside of the first metallic area in a plan view on the laminate (for instance, such a plan view may be from top to bottom in a vertical direction according to FIG. 1). This provides a reinforcement advantageously in a central portion of the second pad and below a central portion of the electronic component to protect the latter against cracks.

In an embodiment, at least one of the first metallic area and the second metallic area is a patterned metal layer. The patterning may be such that the first metallic area and/or the second metallic area may be continuous metallic areas.

In an embodiment, the first metallic area is embedded with direct physical contact in the patterned electrically insulating layer structure and the second metallic area is laterally spaced with respect to the patterned electrically insulating layer structure (see for example FIG. 1). Such a lateral gap does however not disturb the reinforcing effect of the second metallic area.

In an embodiment, the at least one second pad extends at least over substantially an entire width of the electronic component on the carrier. This may ensure a reliable protection of the electronic component against cracks. In particular in the case of large electronic components, such as gallium nitride chips, the electronic component may be prone to cracking and may be reliably protected against cracking by the reinforcing pad.

In an embodiment, the second metallic area is a plating structure. Advantageously, the second metallic area may be formed by a plating process. It has turned out that such a reinforcing plating process may be executed also by a package manufacturer (and thus not necessarily by a laminate substrate manufacturer), so that the additional second metallic area may be flexibly added when a certain package application requires such a reinforcement.

Alternatively, the second metallic area is a solder structure. Thus, it may also be possible to reinforce a second pad by adding a solder material thereon.

In an embodiment, the first metallic area and the second metallic area are made of the same material. This may avoid a material bridge at the interface.

In an embodiment, the first metallic area and/or the second metallic area is or are a copper structure. In particular, the base metal can be copper, due to its superior thermal and electrical conductivity and also processability (for instance what concerns etching and plating). A metallic surface or an activation process on a polymer may be provided to be able to plate copper on top.

In an embodiment, the package comprises an encapsulant, for example a mold compound, at least partially encapsulating the electronic component and being formed at least partially on the carrier. In the context of the present application, the term “encapsulant” may particularly denote a material, structure or member surrounding at least part of the at least one electronic component, and optionally providing electrical insulation and/or a contribution to heat removal during operation. In particular, said encapsulant may be predominantly or even entirely electrically insulating. For instance, said encapsulant may be a laminate-type encapsulant composed of interconnected stacked layers (for instance comprising sheets having resin, and optionally glass fibers). Electrically conductive structures (such as layers and/or arrays of vias) may be arranged on an/or in said encapsulant. Alternatively, the encapsulant may be a mold compound. A mold compound may comprise a matrix of flowable and hardenable material and filler particles embedded therein. For instance, filler particles may be used to adjust the properties of the mold component, in particular to enhance thermal conductivity. As an alternative to a mold compound (for example on the basis of epoxy resin), the encapsulant may also be a potting compound (for instance on the basis of a silicone gel).

In an embodiment, the electrically insulating layer structure comprises a patterned solder resist. A solder resist or solder mask may be a thin film or lacquer-like layer of polymer that may be applied to electrically conductive surface structures for protection against oxidation and/or to prevent unintended solder bridges from forming between closely spaced electrically conductive surface structures.

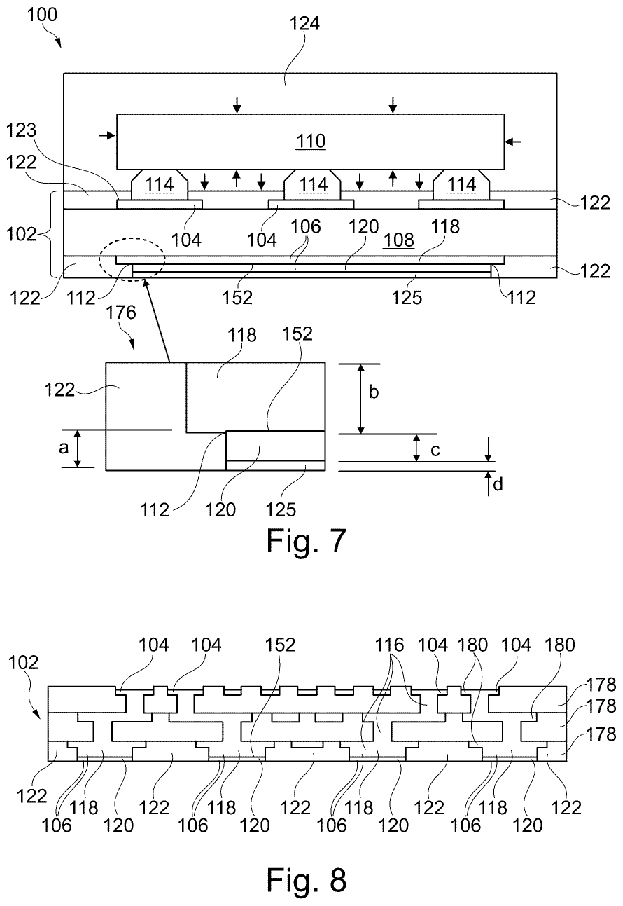

In an embodiment, a lateral air gap is formed between the second metallic area and the electrically insulating layer structure (see FIG. 1). Alternatively, a lateral end of the second metallic area is directly connected with the electrically insulating layer structure without lateral air gap in between (see FIG. 7). Which of the two alternatives is obtained depends on the manufacturing parameter.

In an embodiment, the package comprises a plurality of first pads and/or only one second pad. Each of the first pads may be connected with a respective terminal of the at least one electronic component for establishing an electric connection in between. The single second pad on the bottom side may also have an electric function, but may also be configured for providing a mechanical support function for inhibiting bending and chip crack.

In an embodiment, the package comprises a surface finish on at least one of the at least one first pad and/or on the at least one second pad. For example, a first surface finish (for example organic solderability preservative, OSP) provided on the at least one first pad is different from a second surface finish (for example electroless nickel/electroless palladium/immersion gold, ENEPIG) on the at least one second pad. This may allow to independently adjust the surface finish properties on both opposing main surfaces of the carrier.

In an embodiment, the package comprises a solder structure on at least one of the at least one first pad and/or on the at least one second pad. For instance, it may be possible to apply solder, for instance to print a thin layer to close the gap before molding. Thus, not just plating may be possible on the respective pad, but it may be possible to deposit a thin layer of material, for instance to close an air gap.

In an embodiment, the at least one first pad is electrically connected with the electronic component by an electrically conductive connection structure, for example at least one solder bump. The electrically conductive connection structure may comprise a solder, a sinter material and/or electrically conductive glue. The electrically conductive connection structure may establish an electrically conductive connection between a respective chip terminal of the electronic component and the respective first pad of the carrier.

In an embodiment, the at least one first pad is electrically connected with the at least one second pad by at least one electrically conductive vertical through connection extending through the carrier, for instance through a laminate of the carrier. In the context of the present application, the term “through connection” may particularly denote an electrically conductive structure extending through the entire carrier or part thereof. In an embodiment, at least part of said through connection may extend vertically through the carrier. For example, the through connection may be a metallic post or pillar or a metallic via.

In an embodiment, the method comprises forming the second metallic area before mounting the electronic component on the carrier and/or before forming an encapsulant, for example a mold compound, for at least partially encapsulating the electronic component and for at least partially covering the carrier. Advantageously, the reinforcing second metallic area may already be present when a molding process is carried out. Thus, the package being manufactured can be reliably protected against undesired mechanical load in particular for withstanding the harsh conditions of a subsequent molding process.

In an embodiment, the method comprises forming the second metallic area by a plating process. Such a plating process may comprise an electroless plating process (for instance by an autocatalytic process and/or by sputtering) and/or an electroplating process (for instance galvanic plating).

In an embodiment, the method comprises forming the at least one second pad by providing a preformed first metallic area and by subsequently forming the second metallic area thereon, for example by electroless plating and/or by electroplating. Electrolytic plating is possible. In this case, an additional design on carrier level may be implemented, for instance a bus line.

In an embodiment, the method comprises forming a surface finish on the first metallic area and/or on the second metallic area. This may be accomplished, for example, by electroless plating and/or by electroplating and/or by immersion.

In an embodiment, the electronic component is configured as a power semiconductor chip. Thus, the electronic component (such as a semiconductor chip) may be used for power applications for instance in the automotive field and may for instance have at least one integrated insulated-gate bipolar transistor (IGBT) and/or at least one transistor of another type (such as a MOSFET, a JFET, etc.) and/or at least one integrated diode. Such integrated circuit elements may be made for instance in silicon technology or based on wide-bandgap semiconductors (such as silicon carbide or gallium nitride). A semiconductor power chip may comprise one or more field effect transistors, diodes, inverter circuits, half-bridges, full-bridges, drivers, logic circuits, further devices, etc.

As substrate or wafer forming the basis of the electronic component(s), a semiconductor substrate, preferably a silicon substrate, may be used. Alternatively, a silicon oxide or another insulator substrate may be provided. It is also possible to implement a germanium substrate or a III-V-semiconductor material. For instance, exemplary embodiments may be implemented in gallium nitride or silicon carbide technology.

For the encapsulating, a plastic-like material or a ceramic material which may be subsidized by encapsulant additives such as filler particles, additional resins or others may be used.

The above and other objects, features and advantages of the present invention will become apparent from the following description and the appended claims, taken in conjunction with the accompanying drawings, in which like parts or elements are denoted by like reference numbers.

The illustration in the drawing is schematically and not to scale.

Before exemplary embodiments will be described in more detail referring to the figures, some general considerations will be summarized based on which exemplary embodiments have been developed.

Laminate substrates are increasingly used as chip carrier for power packages due to its potential to reroute current and heat in an efficient manner. Traditional power packages typically have big pads to improve thermal conductivity. Often, modern power laminate packages are forced to conform to a footprint of existing power leadframe packages (for instance a QFN-type package having a big, exposed pad) to enable design-in to an existing board. However, a big pad opening for a laminate package may lead to pad bulging, solder joint crack and chip crack. In particular, a substrate bulge (for instance a bend down phenomenon) may occur when mold pressure is applied to the package being manufactured. As the substrate bends down, a tin bump and a chip may be pulled down by the substrate. As a result, the chip may be cracked when the bending stress exceeds the chip breaking strength.

A conventional solution of this issue is the use of a smaller solder mask opening for a bottom pad. However, this may involve the limitation that the footprint may become incompatible to an existing board footprint.

Another conventional solution of this issue is the use of a reinforced pad with solder mask grids. However, the extra solder mask grid may be inacceptable in view of footprint requirements of certain applications.

Yet another conventional solution of this issue is the implementation of compression molding, which may however increase the manufacturing effort.

According to an exemplary embodiment, a package may be formed on the basis of a carrier (for example a laminate) with first pad(s) on one side and with second pad(s) in a patterned electrically insulating layer structure on the other side. An electronic component (for example a semiconductor die) may be surface mounted on the carrier so as to be electrically coupled with the first pad(s). Beneficially, the second pad(s) may not only be a single layer but may comprise a stack of a first metallic area and an additional second metallic area connected with each other at a (in particular visible or detectable) interface. Hence, a reinforced double layer or multilayer pad may be provided on the carrier opposing the surface mounted electronic component for increasing the mechanical strength. For example, the second metallic area may be plated on the first metallic area for thickening the second pad(s) for enhancing its mechanical support function. Advantageously, such a second pad may suppress or inhibit artefacts such as pad bulging, associated chip crack, solder joint crack, etc. Consequently, a mechanically highly reliable package may be created. In particular, a package with additional support at a bottom pad may be provided by using for example an additional solder mask covering, which may reduce or prevent pad bulging and associated chip crack. In particular large chips (such as gallium nitride chips) may be prone to chip crack, and may be protected against such cracks according to advantageous embodiments.

For example, exemplary embodiments may provide a package with gallium nitride semiconductor chip having for instance dimensions of 6 mm×5 mm or more. Even in such a challenging scenario, the package may be manufactured without the risk of cracks by suppressing bulging by using a reinforced pad composed of at least two stacked metallic areas.

An exemplary embodiment provides a laminate package with step support pad.

Such a package may be formed by step plating on a bottom pad to provide support. More specifically, effective mechanical support against pressure from a mold compound during a mold transfer process may be achieved. Such an effective mechanical support on the bottom pad may prevent or reduce pad bulging and an associated risk of chip crack.

Exemplary embodiments have advantages: Firstly, the manufactured package may achieve footprint compatibility with a target package design (for instance a QFN-like footprint) with build in robustness thanks to the reinforced second pad. Moreover, exemplary embodiments may enhance thermal performance due to the reinforced at least one second pad, for instance as a result of more metallic pad material, such as an increased copper volume. Such an increased metallic volume may contribute to removal of heat created by the at least one electronic component during operation of the package. Beyond this, an enhanced temperature cycling on board (TCoB) characteristics may be obtained. An exemplary embodiments may carry out an additional plating process on a big bottom pad opening of a package to provide mechanical support while being able to maintain footprint planar geometry.

In a method according to exemplary embodiments, a carrier or substrate may be provided with exposed bottom pad (which may be the at least one second pad prior to formation of the second metallic area on the already existing first metallic area). A dielectric layer with a height difference to the pad may partially embed the preform of the at least one second pad. Furthermore, an additional pad layer (which may be the second metallic area) may be added to the first metallic area for completing formation of the at least one second pad and for reinforcing the package and its constituents to suppress warpage, chip crack and bending. Beneficially, the second pad may be a double-layer or a layer being a stack of two or more metallic areas. After the additional plating process for forming the second metallic area, the height difference between the bottom of the solder mask and the bottom of the second pad may be at least reduced. For instance, such a height difference may be partially or entirely compensated by the additional plating of the second metallic area. For example, a vertical extension or gap between solder mask and second pad may be less than 50 μm, for instance less than 10 μm.

FIG. 1 shows a cross-sectional view of a package 100 according to an exemplary embodiment. To put it shortly, the embodiment of FIG. 1 shows a package 100 obtained by carrying out an additional plating process to provide an effective mechanical support for a bottom pad.

The illustrated package 100 may be a semiconductor power package. The package 100 comprises a laminate-type carrier 102 having a top-sided first main surface at which a plurality of metallic first pads 104 are formed side-by-side, for instance all at the same vertical level. At an opposing bottom-sided second main surface of the carrier 102, one metallic second pad 106 is formed. As shown, the second pad 106 is partially embedded in a patterned electrically insulating layer structure 122 of the carrier 102 and is exposed partially beyond the electrically insulating layer structure 122. Correspondingly, also the first pads 104 are embedded in an electrically insulating layer structure 122 of the carrier 102 on the other main surface thereof and are exposed partially beyond the electrically insulating layer structure 122. For instance, each of the two electrically insulating layer structures 102 is a patterned layer of solder resist.

An electronic component 110, which may be a semiconductor power chip, is assembled or mounted on the carrier 102 by an electrically conductive connection structure 114. In the shown embodiment, the electrically conductive connection structure 114 is embodied as a number of solder bumps, so that electrically conductive terminals of the electronic component 110 are electrically and mechanically coupled with the first pads 104 by a solder connection established by the solder-type electrically conductive connection structure 114. Consequently, each of said terminals of the electronic component 110 is electrically connected with an assigned one of the first pads 104. The surface mounted electronic component 110 is arranged vertically spaced with respect to the second pad 106 by the carrier 102.

Advantageously, the bottom-sided second pad 106 is composed of a first metallic area 118 facing a laminate 108 of the carrier 102 and a second metallic area 120 connected at an interface 152 with the first metallic area 118. Any of the metallic areas 118, 120 may be a continuous, structured or spatially limited metal layer of constant or varying thickness. The metallic areas 118, 120 may be made of the same material (for example copper) or may be made of different materials. As shown, the second metallic area 120 faces away from the carrier 102 and from the surface mounted electronic component 110.

Optionally, a surface finish 125 may be formed on an exterior surface of the second metallic area 122 to form an exterior main surface of the package 100. A corresponding surface finish 123 may also be formed on an exposed surface of the first pads 104. For example, the surface finish 123 may be an organic solderability preservative (OSP), whereas the surface finish 125 may be for example electroless nickel/electroless palladium/immersion gold (ENEPIG).

The first metallic area 118 may be formed during manufacture of the carrier 102. Thus, the first metallic area 118 may be created during a laminate substrate manufacturing process executed by a laminate substrate manufacturer. In contrast to this, the second metallic area 120 may be formed in the framework of a component assembly process during which the electronic component 110 is assembled on the carrier 102. Hence, the second metallic area 120 may be created by an additional plating process by a package manufacturer. The second metallic area 120 may be a plating structure which may be formed by electroless plating and/or electroplating. Advantageously, the second pad 106 comprises not only the carrier-sided first metallic area 118, but additionally the thickening second metallic area 120 with the visually or inspectable interface 152 in between. Thus, the first metallic area 118 and the second metallic area 120 may form a stacked metallic double layer. This construction of the second pad 106 may avoid undesired bending or warpage of the carrier 102 when assembling the electronic component 110 thereon. The second pad 106 formed as a combination of the two metallic areas 118, 120 may function as a reinforced pad providing efficient mechanical support. The reinforced second pad 106 may prevent or reduce pad bulging, associated chip crack, solder joint crack, etc., so that package 100 may show excellent properties in terms of mechanical integrity, stability and robustness against bending and cracks.

Still referring to FIG. 1, a height difference between an exterior bottom-sided surface of the second pad 106 and an exterior surface of the bottom-sided electrically insulating layer structure 122 may be very small thanks to the addition of the second metallic area 120, for example may be not more than 10 μm. In the shown embodiment, the bottom-sided exterior surface of the second pad 106 does not protrude downwardly beyond an exterior bottom-sided surface of the electrically insulating layer structure 122. On the contrary, the bottom sided surface of the electrically insulating layer structure 122 may form the lowermost portion of the package 100. Preferably but not necessarily, there may remain a small height difference (preferably not more than 10 μm) so that the bottom main surface of the package 100 is still formed by the solder resist-type electrically insulating layer structure 122. Consequently, a footprint of a conventional package may be maintained, which may simplify compliance with well-defined package assembly processes.

As shown in FIG. 1 as well, the second pad 106 has a step 112 formed between the first metallic area 118 and the second metallic area 120. More specifically, the first metallic area 110 may have a lateral extension being larger than a lateral extension of the second metallic area 120 (or vice versa, not shown), which leads to the formation of step 112. In other words, the first metallic area 118 extends over a wider spatial range than the second metallic area 120. Consequently, the second metallic area 120 lies completely inside of the first metallic area 118 in a plan view onto the laminate 108 along a vertical direction from the top side towards the bottom side of the package 100. In FIG. 1, a lateral air gap 130 is formed between the second metallic area 120 and the electrically insulating layer structure 122. While the first metallic area 118 is partially embedded in the electrically insulating layer structure 122 on the bottom side of the carrier 102 with direct physical contact, the second metallic area 120 lies vertically within but is completely exposed beyond that electrically insulating layer structure 122. Thus, the second metallic area 120 is only connected with direct physical contact to the first metallic area 118 and to the optional surface finish 125, but not to the bottom-sided electrically insulating layer structure 122. Consequently, the first metallic area 118 is embedded with direct physical contact in the patterned electrically insulating layer structure 122 while the second metallic area 120 is laterally spaced with respect to the patterned electrically insulating layer structure 122. As shown in FIG. 1, the second pad 106 extends over an entire width of the electronic component 110 on the carrier 102. This may provide a pronounced reinforcing functionality of the second pad 106 for efficiently suppressing warpage, bending and crack of electronic component 110.

Now referring to the construction of the carrier 102 in further detail, said laminate-type carrier 102 comprises a laminate substrate having a partially electrically insulating laminate 108 between the first main surface and the second main surface of the carrier 102. For example, the partially electrically insulating laminate 108 may comprise one or more resin sheets with reinforcing glass particles, for instance prepreg or FR4 sheets. The partially electrically insulating laminate 108 may also comprise one or more metallic layers, such as structured copper foils and/or plated copper layers. The various layers of the laminate 108 may be interconnected by lamination. As indicated schematically in FIG. 1, said laminate 108 may also comprise one or more electrically conductive vertical through connections 116 extending through the laminate 108 between the pads 104, 106. For example, such an electrically conductive vertical through connection 116 may be one or multiple stacked copper vias and/or one or multiple stacked copper pillars. By vertical through connections 116, short electric and/or thermal paths may be obtained which may ensure signal integrity and/or proper thermal performance.

As shown as well in FIG. 1, the electronic component 110 being surface mounted on the carrier 102 is encapsulated in an encapsulant 124, for example a mold compound. As illustrated, the mold-type encapsulant 124 fully encapsulates the electronic component 110 and is formed on the carrier 102 so as to cover also the upper electrically insulating layer structure 122 and the electrically conductive connection structure 114. The encapsulant 124 mechanically protects and electrically insulates the electronic component 110. Thanks to the reinforcing effect of the additional second metallic area 120, the second pad 106 provides a reliable mechanical protection against warpage, bending and chip crack during a molding process or, more generally, an encapsulation process. To put it shortly, an additional step plating process for forming second metallic area 120 may provide effective mechanical support for the bottom pad 106.

FIG. 2 shows a transparent top view of a package 100 according to an exemplary embodiment. The general design of the package 100 according to FIG. 2 corresponds to the general design of the package 100 according to FIG. 1. However, the illustration in FIG. 1 is more schematic, whereas the illustration FIG. 2 shows a more refined design. Also FIG. 2 illustrates that step plating on a big bottom pad opening provides mechanical support while being able to maintain a footprint planar geometry.

The plan view of FIG. 2 shows an additional pad 156 and a chip marking 158 indicating a position of placing electronic component 110. For instance, the various first pads 104 may comprise source pads and drain pads. However, the detailed arrangement and configuration of the first pads 104 depends on a specific application and chip design.

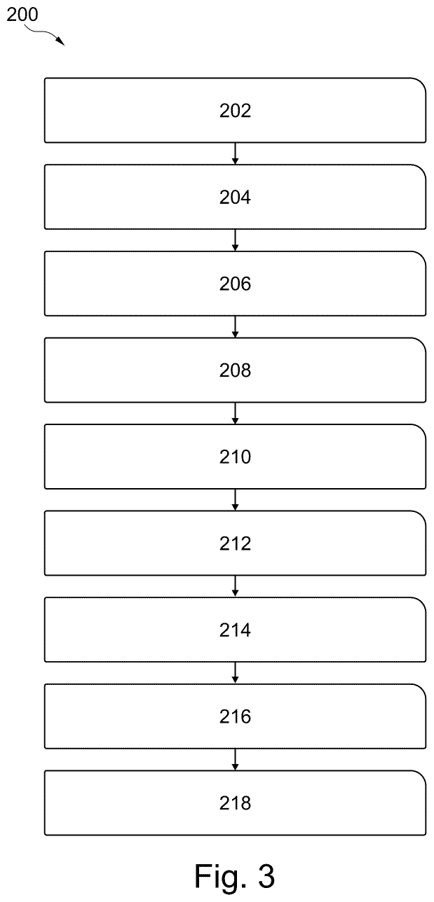

FIG. 3 shows a flowchart 200 of a method of manufacturing a package 100 according to an exemplary embodiment.

Generally, the method of manufacturing package 100 may comprise forming first pads 104 at a first main surface of a carrier 102 and a second pad 106 at an opposing second main surface of the carrier 102. Each of the first pads 104 and the second pad 106 may be arranged partially in an electrically insulating layer structure 122, such as a patterned solder resist, at a respective main surface of the carrier 102. The method may further comprise mounting an electronic component 110 on the carrier 102 to establish an electric connection of one or more terminals of the electronic component 110 with the first pads 104. Due to the surface mounting of the electronic component 110, the electronic component 110 may be vertically spaced with respect to the second pad 106 with the carrier 102 in between. The method may further comprise forming the second pad 106 with a first metallic area 118 facing the carrier 102 and with a separately and later formed second metallic area 120. The metallic areas 118, 120 are connected with each other at a physical or structural interface 152 in between. Preferably, the method comprises forming the second metallic area 120 on the first metallic area 118 by a plating process and in a way to partially compensate a height difference between a bottom surface of the first metallic area 118 and a bottom surface of the electrically insulating layer structure 122. Moreover, the method may comprise forming the second metallic area 120 before mounting the electronic component 110 on the carrier 102 and before forming a mold-type encapsulant 124 for encapsulating the electronic component 110 and for covering the carrier 102. In particular, the method may comprise forming the second pad 106 by providing a preformed first metallic area 118 and by subsequently forming the second metallic area 120 thereon, for example by electroless plating. Optionally, the method comprises forming a surface finish 125 on the second metallic area 120, for example by electroless plating and/or by immersion.

In a first option, step plating for forming second metallic area 120 may be done by a laminate substrate manufacturer. More specifically, the plating process for forming the second metallic area 120 on the first metallic area 118 may be carried out during manufacture of carrier 102, for instance during manufacturing a laminate substrate. Manufacturing a laminate substrate may comprise processes such as drilling holes in a laminate comprising copper and resin, copper plating, dry film lamination, exposure and development, etching, routing and forming a surface finish. In this context, also a thickening of a bottom-sided pad comprising a first metallic area 118 by forming a second metallic area 120 thereon may be executed during laminate substrate manufacture.

In a second option, the plating process for forming the second metallic area 120 on the first metallic area 118 may be carried out during a chip assembly and encapsulation process based on a pre-manufactured laminate substrate. Such a process may be carried out by a package manufacture rather than by a laminate substrate manufacturer. More specifically, step plating using an Electroless Nickel Immersion Gold process may be done at a package manufacturer side.

A corresponding process flow for a step plating process executed according to said second option is shown as flowchart 200 in FIG. 3.

Referring to a block 202, a pretreatment with an organic acid dip may be carried out.

Referring to a block 204, a microetching process may be executed.

Referring to a block 206, an acid dip may be carried out.

Referring to a block 208, a palladium activator may be provided.

Referring to a block 210, an acid dip may be executed.

Referring to a block 212, an electroless nickel process may be carried out.

Referring to a block 214, an immersion gold process may be executed.

Referring to a block 216, a post treatment can be made.

Referring to a block 218, a drying process may be executed.

In the scenario according to FIG. 3, a laminate substrate may be obtained from a laminate substrate manufacturer with only a copper plating for the bottom pad 106, i.e. with first metallic area 118 but still without second metallic area 120.

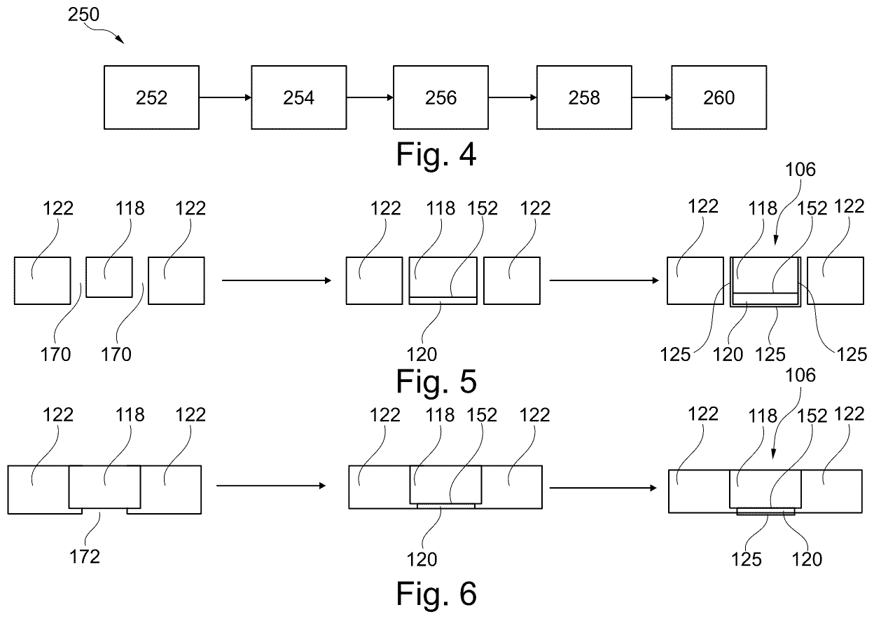

FIG. 4 shows a flowchart 250 of a method of manufacturing a package 100 according to an exemplary embodiment.

Referring to a block 252, an incoming laminate substrate may be obtained with no plating, and full OSP copper structure. More generally, carrier 102 may be obtained with bottom pad 106 comprising only first metallic area 118.

Referring to a block 254, a high speed electroless copper plating process may be executed. More generally, second metallic area 120 may be plated on first metallic area 118.

Referring to a block 256, a chip assembly process may be carried out followed by molding and post-mold curing. When assembling electronic component 110 on carrier 102 and forming the encapsulant 124 after reinforcing second pad 106 by the formation of second metallic area 120 in block 254, the package 100 being presently manufactured may be protected against warpage and chip crack. Thus, it may be advantageous to execute molding after high-speed plating. Consequently, a compression force during molding is no longer an issue for package 100 and its constituents.

Referring to a block 258, an electroless NiPAu plating process may be executed.

Referring to a block 260, additional processing, such as laser marking, package singulation, etc., may be carried out.

FIG. 5 shows cross-sectional views of structures obtained during manufacturing a package 100 according to an exemplary embodiment. The process according to FIG. 5 may start from a non-solder mask defined pad.

As shown on the left-hand side of FIG. 5, first metallic area 118 (such as a copper pad) is arranged in an opening of patterned electrically insulating layer structure 122 (for instance a solder mask). As shown, there is a horizontal gap 170 between the first metallic area 118 and the patterned electrically insulating layer structure 122.

As shown in the central portion of FIG. 5, second metallic area 120 is plated on the exposed bottom surface of the first metallic area 118 for completing manufacture of second pad 106. Thus, pad reinforcement is carried out for mitigating a bottom-sided height difference between patterned electrically insulating layer structure 122 and first metallic area 118. For instance, second metallic area 120 is formed with such a thickness (for instance in a range from 10 μm to 15 μm) that the bottom surface of the obtained second pad 106 is in flush or substantially in flush with the bottom surface of the patterned electrically insulating layer structure 122. This may be denoted as same level plating by forming a bottom-sided stand-off bump in form of second metallic area 120.

As shown on the right-hand side of FIG. 5, remaining gaps between patterned electrically insulating layer structure 122 and the stacked first and second metallic areas 118, 120 may be filled at least partially by a surface finish 125. For example, a thickness of the surface finish 125 may be in a range from 3 μm to 10 μm, in particular in a range from 6 μm to 7 μm.

FIG. 6 shows cross-sectional views of structures obtained during manufacturing a package 100 according to another exemplary embodiment.

The embodiment of FIG. 6 differs from the embodiment of FIG. 5 in particular in that, according to FIG. 6, sidewalls of first metallic area 118 are in direct physical contact with sidewalls of patterned electrically insulating layer structure 122. Furthermore, a peripheral portion of the bottom wall of the first metallic area 118 is covered by material of the patterned electrically insulating layer structure 122. However, a central portion of the bottom wall of the first metallic area 118 is exposed beyond the patterned electrically insulating layer structure 122 so as to define a bottom-sided opening 172. Formation of the second metallic area 120 on the exposed bottom-sided surface of the first metallic area 118 at least partially fills the opening 172. Thereafter, surface finish 125 may be applied to the exposed bottom-sided surface of the second metallic area 120.

FIG. 7 shows a cross-sectional view of a package 100 according to another exemplary embodiment together with a detail 176.

The embodiment of FIG. 7 differs from the embodiment of FIG. 1 in particular in that, according to FIG. 7, no gap 130 is formed between the second pad 106 and the electrically insulating layer structure 122. In other words, an entire lateral end of the second metallic area 120 is directly connected with direct physical contact with the electrically insulating layer structure 122 without lateral air gap in between.

In contrast to a conventional incoming substrate having a step gap due to solder mask opening, the embodiment of FIG. 7 executes an additional step plating process which provides effective mechanical support for bottom pad 106. For example, NiAu may be applied as final plating for forming surface finish 125 for promoting solderability.

Detail 176 shows geometric parameters of package 100 around step 112. For example, a height of the portion of the patterned electrically insulating layer structure 122 protruding beyond first metallic area 118 may be denoted as “a” and may be in a range from 13 μm to 27 μm. For instance, a vertical thickness of first metallic area 118 may be denoted as “b” and may be in a range from 60 μm to 80 μm. For example, a vertical thickness of the second metallic area 120 may be denoted as “c” and may be in a range from 15 μm to 21 μm. For instance, a vertical thickness of the surface finish 125 may be denoted as “d” and may comprise a sublayer of nickel with a thickness in a range from 0.5 μm to 2.5 μm and may comprise a further sublayer of gold having a thickness in a range from 0.03 μm to 0.25 μm. Other thicknesses are possible as well.

FIG. 8 shows a cross-sectional view of a molded interconnected substrate-type carrier 102 for a package 100 according to another exemplary embodiment.

The embodiment of FIG. 8 differs from the embodiment of FIG. 1 in particular in that, according to FIG. 8, carrier 102 comprises a Molded Interconnect Substrate (MIS), rather than a laminate substrate. Hence, packages 100 according to exemplary embodiments may also be implemented with non-laminate carriers.

Referring to the carrier 102 according to FIG. 8, a plurality of mold layer structures 178 (for instance comprising epoxy mold compound) may be stacked on top of each other. A plurality of trace layer structures 180 may be embedded in the mold layer structures 178. Furthermore, vertical through connections 116, such as copper pillars, may be embedded in the mold layer structures 178 as well and may be electrically coupled with the trace layer structures 180. Also the carrier 102 according to FIG. 8 may comprise patterned electrically insulating layer structures 122 (such as a solder mask) on its bottom main surface and/or on its top main surface.

Hence, FIG. 8 illustrates that a package 100 according to an exemplary embodiment may also be formed using another routable carrier than a laminate substrate, for example the illustrated Molded Interconnect Substrate (MIS) carrier. Carrier 102 of FIG. 8 may be a routable carrier where traces are held by using Epoxy Molding Compound (EMC). Also the illustrated MIS carrier can have a gap between a copper pad and the carrier body.

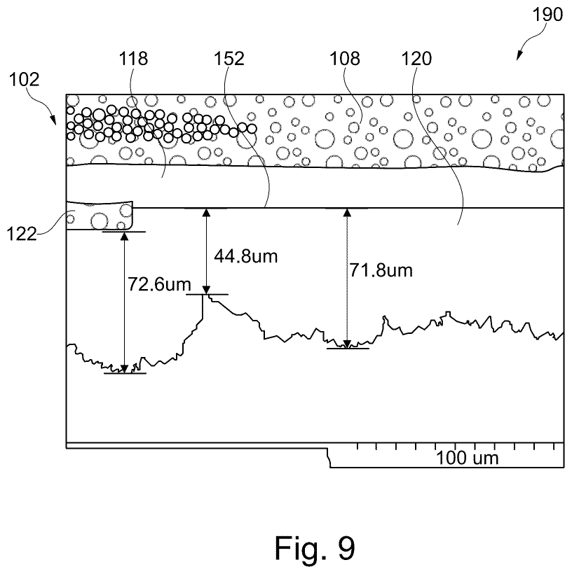

FIG. 9 shows a cross-sectional image 190 of part of a package 100 according to an exemplary embodiment. In particular, the interface 152 between first metallic area 118 and second metallic area 120 is visible in the illustrated cross-sectional view.

FIG. 9 shows the results of a support pad copper plating. Hence, FIG. 9 demonstrates that it is feasible to plate over a copper pad. In FIG. 9, excessive plating over the solder mask is due to a long plating time. However, the plating time may be shortened to obtain any desired thickness of the second metallic area 120. With shorter plating time, it may be possible that no copper will be plated over the solder mask. Furthermore, roughness properties, etc. can be further improved by modifying plating time, concentration, temperature, and/or solution circulation. According to FIG. 9, adhesion is good as there is no separation gap. Moreover, the copper grain is consistent.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A package, comprising:
a carrier having a first main surface at which at least one first pad is formed and an opposing second main surface at which at least one second pad is formed at least partially in an electrically insulating layer structure of the carrier; and
an electronic component mounted on or above the carrier, electrically connected with the at least one first pad and arranged spaced with respect to the at least one second pad by the carrier;
wherein the at least one second pad comprises a first metallic area facing the carrier and a second metallic area connected at an interface with the first metallic area and facing away from the carrier;
wherein the second pad extends over an entire width of the electronic component on the carrier.

2. The package according to claim 1, wherein a height difference between an exterior surface of the at least one second pad and an exterior surface of the electrically insulating layer structure is not more than 15 μm, for example not more than 10 μm, preferably not more than 5 μm.

3. The package according to claim 1, wherein an exterior surface of the at least one second pad does not protrude downwardly beyond an exterior surface of the electrically insulating layer structure.

4. The package according to claim 1, wherein the at least one second pad has a step.

5. The package according to claim 1, wherein a lateral step is formed between the first metallic area and the second metallic area.

6. The package according to claim 1, wherein the carrier comprises a laminate substrate having an at least partially electrically insulating laminate between the first main surface and the second main surface, and/or comprises a molded interconnect substrate.

7. The package according to claim 1, wherein the at least one second pad is a double layer or a triple layer.

8. The package according to claim 1, comprising one of the following features:
wherein the first metallic area extends over a wider spatial range than the second metallic area;
wherein the second metallic area extends over a wider spatial range than the first metallic area.

9. The package according to claim 1, wherein the second metallic area lies completely inside of the first metallic area in a plan view on the laminate.

10. The package according to claim 1, wherein at least one of the first metallic area and the second metallic area is a patterned metal layer.

11. The package according to claim 1, wherein the first metallic area is embedded with direct physical contact in the patterned electrically insulating layer structure and the second metallic area is laterally spaced with respect to the patterned electrically insulating layer structure.

12. The package according to claim 1, comprising at least one of the following features:
wherein the second metallic area is a plating structure;
wherein the second metallic area is a solder structure;
wherein the first metallic area and the second metallic area are made of the same material;
wherein the first metallic area and/or the second metallic area is or are a copper structure.

13. The package according to claim 1, comprising an encapsulant, for example a mold compound, at least partially encapsulating the electronic component and being formed at least partially on the carrier.

14. The package according to claim 1, wherein the electrically insulating layer structure comprises a patterned solder resist.

15. The package according to claim 1, comprising one of the following features:
a lateral air gap is formed between the second metallic area and the electrically insulating layer structure;
a lateral end of the second metallic area is directly connected with the electrically insulating layer structure without lateral air gap in between.

16. The package according to claim 1, comprising at least one of the following features:
wherein the package comprises a plurality of first pads and/or only one second pad;
wherein the electronic component comprises a power semiconductor chip;
comprising a surface finish on at least one of the at least one first pad and/or on the at least one second pad, wherein for example a first surface finish, for example organic solderability preservative, on the at least one first pad is different from a second surface finish, for example electroless nickel/electroless palladium/immersion gold, on the at least one second pad;
comprising a solder structure on at least one of the at least one first pad and/or on the at least one second pad;
wherein the at least one first pad is electrically connected with the electronic component by an electrically conductive connection structure, for example at least one solder structure;
wherein the at least one first pad is electrically connected with the at least one second pad by at least one electrically conductive vertical through connection extending through the carrier.

17. A method of manufacturing a package, the method comprising:
forming at least one first pad at a first main surface of a carrier;
forming at least one second pad at an opposing second main surface of the carrier and at least partially in an electrically insulating layer structure of the carrier;
mounting an electronic component on or above the carrier, electrically connected with the at least one first pad and arranged spaced with respect to the at least one second pad by the carrier; and
forming the at least one second pad with a first metallic area facing the carrier and with a separately formed second metallic area connected at an interface with the first metallic area and facing away from the carrier;
wherein the second pad extends over an entire width of the electronic component on the carrier.

18. The method according to claim 17, wherein the method comprises forming the second metallic area on the first metallic area to thereby at least partially compensate a height difference between a bottom surface of the first metallic area and a bottom surface of the electrically insulating layer structure.

19. The method according to claim 17, wherein the method comprises forming the second metallic area before mounting the electronic component on the carrier and/or before forming an encapsulant, for example a mold compound, for at least partially encapsulating the electronic component and for at least partially covering the carrier.

20. The method according to claim 17, comprising at least one of the following features:
wherein the method comprises forming the second metallic area by a plating process;
wherein the method comprises forming the at least one second pad by providing a preformed first metallic area and by subsequently forming the second metallic area thereon, for example by electroless plating and/or by electroplating;
wherein the method comprises forming a surface finish on the first metallic area and/or on the second metallic area, for example by electroless plating and/or by electroplating and/or by immersion.
